(19) United States
(12) Patent Application Publication
(10) Pub. No.: US 2025/0298157 A1
(43) Pub. Date: Sep. 25, 2025

(54) PLASMA PARAMETER MEASUREMENT DEVICE

(71) Applicant: Samsung Electronics Co., Ltd., Suwon-si (KR)

(72) Inventors: Jongmin SONG, Suwon-si (KR); Young YOON, Suwon-si (KR); Sungho JANG, Suwon-si (KR); Younsok CHOI, Suwon-si (KR)

(73) Assignee: Samsung Electronics Co., Ltd., Suwon-si (KR)

(21) Appl. No.: 18/820,580

(22) Filed: Aug. 30, 2024

(30) Foreign Application Priority Data
Mar. 25, 2024 (KR) 10-2024-0040210

(51) Int. Cl. G01T 1/24

(52) U.S. Cl. CPC G01T 1/24

(57) ABSTRACT

Various example embodiments relate to, a plasma parameter measurement device comprising an upper plate and a lower plate, comprising a first material, a first sensor including a first collector comprising the first material, and the first material being included in a semiconductor substrate to be subjected to the plasma, and a first insulating structure surrounding a side surface of the first collector and exposing at least a portion of an upper surface of the first collector in a first hole in the upper plate. A second sensor including a second collector comprising the first material, and a second insulating structure surrounding a side surface of the second collector and exposing at least a portion of an upper surface of the second collector in a second hole in the upper plate.

### CROSS-REFERENCE TO RELATED APPLICATION(S)

This application claims benefit of priority to Korean Patent Application No. 10-2024-0040210 filed on Mar. 25, 2024 in the Korean Intellectual Property Office, the disclosure of which is incorporated herein by reference in its entirety.

### BACKGROUND

The present inventive concepts relate to a plasma parameter measurement device.

Plasma processes may be used to manufacture semiconductor devices. Plasma may be formed in a chamber space in which the plasma processes are performed, and the formed plasma may cause an effect such as etching, deposition, or the like on a surface of a semiconductor substrate. To induce desired effects, plasma parameters may be carefully controlled.

In order to effectively control the plasma parameters, it is desirable for the plasma parameters to be monitored in situ in the chamber space.

### SUMMARY

Various example embodiments of the present inventive concepts are to provide a plasma parameter measurement device that may monitor a component of a plasma parameter having directivity in a desired (and/or alternatively predetermined) direction range in situ in a chamber space.

According to various example embodiments of the present inventive concepts, a plasma parameter measurement device includes an upper plate and a lower plate comprising a first material, and the first material being included in a semiconductor substrate to be subjected to the plasma, a first sensor including a first collector comprising the first material, and a first insulating structure surrounding a side surface of the first collector and exposing at least a portion of an upper surface of the first collector in a first hole in the upper plate. A step difference between an upper surface of the first insulating structure and the upper surface of the first collector, relative to a diameter of an exposed surface of the first collector, has a first aspect ratio. A second sensor including a second collector comprising the first material, and a second insulating structure surrounding a side surface of the second collector and exposing at least a portion of an upper surface of the second collector in a second hole in the upper plate, and wherein a step difference between an upper surface of the second insulating structure and the upper surface of the second collector, relative to a diameter of an exposed surface of the second collector, has a second aspect ratio, the second aspect ratio being different from the first aspect ratio, and a circuit substrate between the upper plate and the lower plate, the circuit substrate including a circuit configured to measure a plasma parameter in a direction range, based on a differential signal between a first signal from the first sensor and a second signal from the second sensor.

According to various example embodiments of the present inventive concepts, a plasma parameter measurement device includes an upper plate and a lower plate comprising a first material, and the first material being included in a semiconductor substrate to be subjected to the plasma, a plurality of sensor pairs respectively including a first sensor including a first collector comprising the first material, a first insulating structure surrounding a side surface of the first collector, and the first insulating structure having an upper surface of the first insulating structure being coplanar with an upper surface of the first collector in a hole in the upper plate, a second sensor including a second collector comprising the first material, and a second insulating structure surrounding a side surface of the second collector and having an upper surface protruding relative to an upper surface of the second collector in a hole in the upper plate, and a circuit substrate between the upper plate and the lower plate including a circuit configured to measure a distribution of a plasma parameter in a direction range on an upper surface of the upper plate. The measurement of the distribution of the plasma parameter is based on differential signals acquired by the first sensor and the second sensor in each of the plurality of sensor pairs.

According to various example embodiments of the present inventive concepts, a plasma parameter measurement device includes an upper plate and a lower plate comprising a first material, and the first material being included in a semiconductor substrate to be subjected to the plasma, a circuit substrate between the upper plate and the lower plate and including a circuit, and a sensor including a collector comprising the first material, and the collector including an inner side surface facing the circuit substrate, an outer side surface opposite the inner side surface, an insulating structure surrounding the collector and exposing at least a portion of the outer side surface of the collector, and a signal pad contacting the inner side surface of the collector on a side surface of the circuit substrate. The circuit is configured to measure a plasma parameter in a direction range, based on a signal from the signal pad.

According to various example embodiment of the present inventive concepts, a plasma parameter measurement device includes an upper plate and a lower plate comprising a first material, and the first material being included in a semiconductor substrate to be subjected to the plasma, a sensor in a hole formed in the upper plate, the sensor including a collector comprising the first material, a signal pad contacting a lower surface of the collector, an insulating structure surrounding a side surface of the collector and exposing at least a portion of an upper surface of the collector, the insulating structure having a step difference between the upper surface of the insulating structure and the upper surface of the collector, and an actuator configured to control an angle of the upper surface of the collector, and a circuit substrate between the upper plate and the lower plate and including a circuit configured to measure a plasma parameter in a direction range, based on a signal from the signal pad.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a perspective view schematically illustrating a plasma parameter measurement device according to various example embodiments.

FIG. 2 is a view illustrating an example of a plasma process.

FIG. 3 is a view illustrating an example of a plasma processing device.

FIG. 4 is a cross-sectional view illustrating a portion of a plasma parameter measurement device according to various example embodiments.

FIGS. 5A to 5D are views illustrating a sensor pair in detail, according to various example embodiments.

FIG. 6 is a view illustrating a sensor pair in detail, according to various example embodiments.

FIGS. 7A and 7B are views illustrating a sensor pair in detail, according to various example embodiments.

FIG. 8 is a flowchart illustrating a method for measuring a plasma parameter according to various example embodiments.

FIGS. 9A to 9C are views illustrating a sensor in detail, according to various example embodiments.

FIGS. 10A and 10B are views illustrating a sensor in detail, according to various example embodiments.

FIGS. 11A and 11B are views illustrating a plasma parameter measurement device and distribution of a plasma parameter according to various example embodiments.

FIG. 12 is a flowchart illustrating a method for measuring distribution of a plasma parameter according to various example embodiments.

FIG. 13 is a view illustrating a plasma parameter measurement system according to various example embodiments.

### DETAILED DESCRIPTION

Hereinafter, preferred embodiments will be described with reference to the attached drawings.

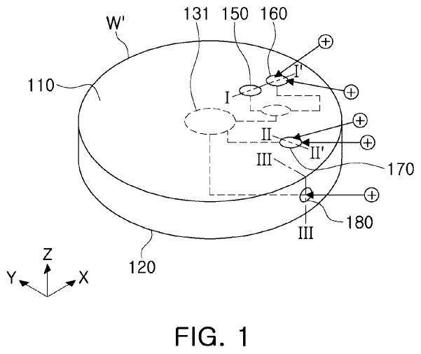

FIG. 1 is a perspective view schematically illustrating a plasma parameter measurement device according to various example embodiments.

Referring to FIG. 1, a plasma parameter measurement device 100 may have a structure W′ having a size and a shape, similar to that of a semiconductor substrate. For example, the plasma parameter measurement device 100 may have a circular shape having a diameter of 100 mm to 500 mm in an X-Y plane and a maximum thickness of 0.5 mm to 3 mm in a Z-direction.

A surface of the plasma parameter measurement device 100 may include an upper plate 110 and a lower plate 120, formed of a material, the same as a material of the semiconductor substrate. For example, when a plasma process is performed on a silicon (Si) substrate, the upper plate 110 and the lower plate 120 may be formed of silicon.

The plasma parameter measurement device 100 may be interchangeable with the substrate. For example, the plasma parameter measurement device 100 may be introduced into a chamber space in which the plasma process is performed in the same manner as the substrate, may perform measurement of a plasma parameter in a state loaded in the chamber space, and may then be removed from the chamber space.

Also, contamination of the chamber space due to the plasma parameter measurement device 100 may be minimized. For example, contamination of the chamber space after measuring the plasma parameter using the plasma parameter measurement device 100 in situ in the plasma process may be similar to contamination after performing the plasma process using the silicon substrate. For example, contamination of the chamber space after measuring the plasma parameter may be purified by a process used to purify the chamber space after performing the plasma process.

In some plasma processes, a plasma parameter having directivity may affect quality of a semiconductor device and productivity of a process. For example, ion flux of positive ions (+) incident on the semiconductor substrate may have directivity depending on an angle at which the positive ions are incident. An etching rate of a side surface of a structure formed on the substrate may affect the productivity of the process, and ion flux of a lateral component may affect the etching rate of the side surface of the structure formed on the substrate. To effectively control the etching rate of the side surface of the structure formed on the substrate, it is desirable that the lateral component of a plasma parameter having directivity, including ion flux, may be monitored in situ in the chamber space.

According to various example embodiments, the plasma parameter measurement device 100 may include sensors 150, 160, 170, and 180 that may measure a component of a plasma parameter having directivity in situ in the chamber space in a desired (and/or alternatively predetermined) direction range, especially in a lateral direction, and a circuit 131 that may collect measurement results of the sensors 150 to 180 in the plasma parameter measurement device 100 and may provide the measurement results externally. The sensors 150 to 180 may include a collector having a surface formed of a material, the same as the material of the semiconductor substrate, and may acquire a value of the plasma parameter in a desired (and/or alternatively predetermined) direction range.

Hereinafter, before a plasma parameter measurement device according to various example embodiments is described in detail, an example of a plasma process will be described, and an example of a plasma processing device into which the plasma parameter measurement device may be introduced will be described.

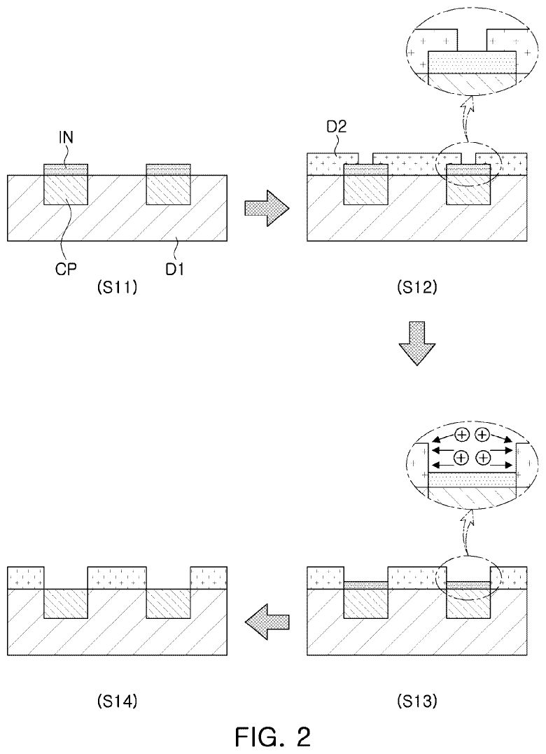

FIG. 2 is a view illustrating an example of a plasma process.

A dielectric-on-dielectric (DoD) process may refer to a process of selectively depositing a second dielectric layer on a surface of a patterned first dielectric layer. When the DoD process is used, since the second dielectric layer may not be deposited on a conductive pattern on an upper surface of a substrate and may be selectively deposited on the surface of the first dielectric layer, alignment of vias may be improved. The DoD process may include S11 to S14 of FIG. 2.

A substrate W may include a first dielectric layer D1 patterned with a conductive pattern CP. In S11, an inhibitor IN may be deposited on an upper surface of the conductive pattern CP.

In S12, a second dielectric layer D2 may be selectively deposited on an upper surface of the substrate W. Specifically, due to the inhibitor IN deposited on the upper surface of the conductive pattern CP, the deposition of the second dielectric layer D2 may be avoided on the upper surface of the conductive pattern CP, and the second dielectric layer D2 may be deposited on an upper surface of the first dielectric layer D1.

When a thickness level on which the second dielectric layer D2 is deposited is higher than a thickness level on which the inhibitor IN is deposited, a side surface of the second dielectric layer D2 may be exposed, and a dielectric material may be deposited on the exposed side surface. Therefore, a mushrooming phenomenon may occur in which the side surface of the second dielectric layer D2 has an expanded mushroom-shaped shape.

The mushrooming phenomenon may deteriorate quality of the substrate W. In S13, an etching process may be performed to etch a laterally expanded portion of the second dielectric layer D2. Due to the etching process, the expanded portion may be removed, and a surface on which the inhibitor IN is deposited may be exposed.

In S14, post-processing may be performed to remove the inhibitor IN and expose a surface of the conductive pattern CP formed on the first dielectric layer D1.

The etching process of S13 may be performed, when positive ions (+) contained in plasma collide with the upper surface of the substrate W. Amounts of positive ions reaching a given area of the substrate may be referred to as ion flux.

The positive ions may incident in various directions, and may collide with the upper surface of the substrate. For example, the ion flux may have directivity. When the ion flux according to direction is not controlled in the etching process, not only a side surface but also an upper surface of the second dielectric layer D2 may be etched, and a thickness of the second dielectric layer D2 may decrease. When an operation of depositing the second dielectric layer D2 in S12 and an operation of etching the second dielectric layer D2 in S13 should be repeated to form a target thickness of the second dielectric layer D2, a time period required for the DoD process may increase.

When the direction of the ion flux may be controlled, the side surface of the second dielectric layer D2 may be effectively etched in the etching process, and a time period for forming the target thickness of the second dielectric layer D2 may decrease.

According to various example embodiments, a plasma parameter measurement device capable of measuring a plasma parameter having directivity, including ion flux, may be proposed.

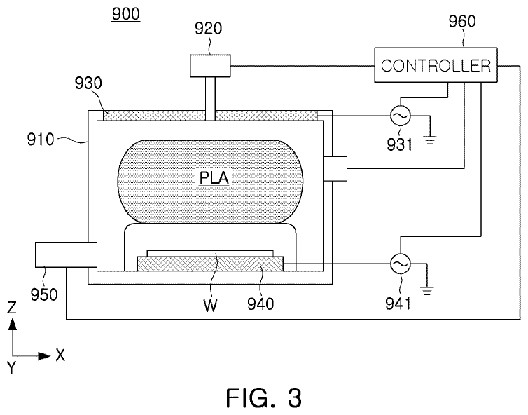

FIG. 3 is a view illustrating an example of a plasma processing device.

Referring to FIG. 3, a plasma processing device 900 may include a chamber body 910, a gas supply device 920, an upper electrode 930, a first power device 931, an electrostatic chuck 940, a second power device 941, an exhaust device 950, and a controller 960.

The chamber body 910 may serve as a housing forming a chamber space CH defined by an external wall. The chamber space CH may be used to perform a plasma process of treating a substrate W to be processed using plasma PLA generated by exciting a process gas supplied by the gas supply device 920. The external wall may be formed of a material having excellent wear resistance and corrosion resistance. The chamber body 910 may maintain the chamber space CH in a sealed state with a desired (and/or alternatively predetermined) pressure and a desired (and/or alternatively predetermined) temperature during the plasma process, for example, an etching process. The exhaust device 950 may be disposed on the external wall of the chamber body 910 to exhaust gas from an internal space.

The gas supply device 920 may supply the process gas for performing the plasma process to the chamber space CH.

The upper electrode 930 may be disposed on an upper portion of the chamber body 910. A first high-frequency power, for example, an RF power, may be applied to the upper electrode 930 by the first power device 931.

The electrostatic chuck 940 may be disposed in the chamber space CH, and may fix the substrate W on an upper surface using static electricity. A second high-frequency power, for example, an RF power, may be applied to the electrostatic chuck 940 by the second power device 941. For example, the electrostatic chuck 940 may serve as a lower electrode.

The process gas supplied from the gas supply device 920 may be converted into a plasma PLA state by at least one of the first high-frequency power applied to the upper electrode 930, or the second high-frequency power applied to the electrostatic chuck 940. Also, positive ions contained in the plasma PLA may incident on the substrate W by the second high-frequency power, to perform the plasma process.

The exhaust device 950 may discharge the process gas in the chamber space CH externally to depressurize the chamber space. For example, the exhaust device 950 may include a pump device.

The controller 960 may control an overall operation of the gas supply device 920, the first power device 931, the second power device 941, the exhaust device 950, or the like. However, example embodiments are not limited thereto.

A size of a path for introducing the substrate W into the chamber space CH may be limited, and since the chamber space CH should be maintained in a sealed state, it may be difficult to arbitrarily open and close the chamber space CH. Therefore, a thickness of the plasma parameter measurement device for measuring a plasma parameter in a state introduced into the chamber space CH may be limited, depending on an introduction path into the chamber space CH. For example, a plasma processing device 900 may be manufactured such that the chamber space CH has a space capable of accommodating a substrate having a thickness of 775 um, and an object having a thickness of up to or about 1.5 mm may be introduced into the chamber space CH. In the plasma processing device 900, only a plasma parameter measurement device having a maximum thickness of about 1.5 mm or less may be introduced into the chamber space CH to perform plasma parameter measurement.

When a sensor structure having an inclined surface should be formed on an upper surface of the plasma parameter measurement device to measure a plasma parameter in a desired (and/or alternatively predetermined) direction range, for example, a lateral direction, the sensor structure may have a large thickness. Therefore, it may be difficult to manufacture a plasma parameter measurement device satisfying a thickness limit.

According to various example embodiments, a plasma parameter measurement device may have a size and a shape, similar to that of a semiconductor substrate, and a plasma parameter in a lateral direction may be measured using at least one of a sensor structure formed on an upper surface, a sensor structure having a surface, parallel to an upper surface of the substrate, or a sensor structure formed on a side surface.

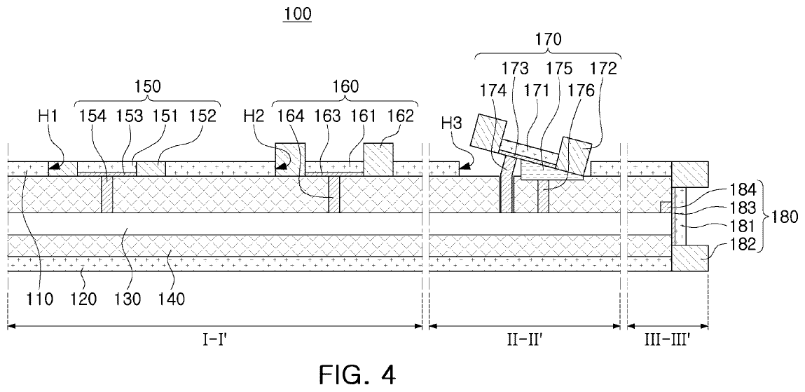

Hereinafter, a plasma parameter measurement device according to various example embodiments will be described in detail with reference to FIGS. 4 to 13.

FIG. 4 is a cross-sectional view illustrating a portion of a plasma parameter measurement device according to various example embodiments. Specifically, FIG. 4 illustrates cross-sections taken along lines II-I′, II-II′, and III-III′ of a plasma parameter measurement device 100, as described with reference to FIG. 1.

Referring to FIG. 4, a plasma parameter measurement device 100 may include an upper plate 110, a lower plate 120, a circuit substrate 130, a filling material 140, and a plurality of sensors 150 to 180.

The upper plate 110 and the lower plate 120 may be formed of a material, the same as a material of a semiconductor substrate processed in a plasma process, for example, silicon (Si). Additionally, the upper plate 110 and the lower plate 120 may have a shape and a size, identical or similar to a shape and a size of the semiconductor substrate, respectively. For example, the upper plate 110 and the lower plate 120 may be formed in a circular shape with a diameter of 100 mm to 500 mm, respectively.

Since the shapes of the upper plate 110 and the lower plate 120 are similar to the semiconductor substrate, the plasma parameter measurement device 100 may be introduced into a chamber space in the same manner as the semiconductor substrate, and since materials of the upper plate 110 and the lower plate 120 are the same as that of the semiconductor substrate, contamination of the chamber space may be minimized.

An upper surface of the upper plate 110 may correspond to an upper surface of the semiconductor substrate, and a lower surface of the lower plate 120 may correspond to a lower surface of the semiconductor substrate. For example, when measurement of a plasma parameter is performed, the upper surface of the upper plate 110 may be exposed to plasma in the chamber space CH. Additionally, the lower surface of the lower plate 120 may be fixed to an electrostatic chuck.

First to third sensors 150, 160, and 170 may be disposed in a plurality of holes H1, H2, and H3 formed in the upper plate 110. Additionally, a fourth sensor 180 may be disposed on a side surface of the upper plate 110 and a side surface of the lower plate 120.

The circuit substrate 130 including a circuit may be disposed between the upper plate 110 and the lower plate 120. The circuit substrate 130 may collect a signal from the plurality of sensors 150 to 180, may measure the plasma parameter, based on the signal, and may transmit information of the measured plasma parameter externally.

Between the upper plate 110 and the circuit substrate 130 and between the lower plate 120 and the circuit substrate 130 may be filled with the filling material 140. The filling material 140 may fix and support the upper plate 110, the lower plate 120, the circuit substrate 130, and the plurality of sensors 150 to 180, and may maintain the circuit substrate 130 in a vacuum state.

The plurality of sensors 150 to 180 may have a surface exposed to the plasma, and may convert amounts of positive ions which incident on the surface into a signal. For example, the signal may be an electrical signal such as a current signal.

The first sensor 150 and the second sensor 160 may form a sensor pair, based on a differential signal between a first signal generated from the first sensor 150 and a second signal generated from the second sensor 160. Thus, the plasma parameter in a desired (and/or alternatively predetermined) direction range may be measured.

The first sensor 150 may include a first collector 151, a first insulating structure 152, a first signal pad 153, and a first signal line 154.

The first collector 151 may have an upper surface exposed to the plasma, and may collect positive ions incident on the upper surface. The first collector 151 may be formed of a material, the same as the material of the semiconductor substrate, and may collect positive ions under an environment, the same as a plasma process environment. The upper surface of the first collector 151 may be parallel to the upper surface of the upper plate 110. In various example embodiments, the upper surface of the first collector 151 may be substantially coplanar with the upper surface of the upper plate 110.

The first insulating structure 152 may have a structure surrounding a side surface of the first collector 151. The first insulating structure 152 may electrically separate the first collector 151 and the upper plate 110. In various example embodiments, an upper surface of the first insulating structure 152 may be substantially coplanar with the upper surface of the first collector 151. For example, a step difference between the upper surface of the first insulating structure 152 and the first collector 151 may be ‘0.’ In this case, the fact that the step difference is ‘0’ may also include cases in which the step difference may be within a tolerance range.

In various example embodiments, the first insulating structure 152 may include at least one of quartz or glass. Since quartz and glass are stable materials, contamination of the chamber space may be minimized even when the plasma process is performed while exposed to the chamber space.

The first signal pad 153 may convert positive ions incident on a surface of the first collector 151 into a signal. For example, the first signal pad 153 may include a conductive material, and may convert positive ions into an electrical signal. A different amount of current may be generated in the first signal pad 153, depending on amounts of the positive ions incident on the surface of the first collector 151 per hour. The first signal pad 153 may be disposed on a side surface of the first collector 151, not exposed to the plasma.

In various example embodiments, the first signal pad 153 may include at least one of gold (Au) or tungsten (W).

In various example embodiments, the first signal pad 153 may be formed by depositing, plating, or sputtering a metal on one surface of the first collector 151. In various example embodiments, the first signal pad 153 may be formed by attaching a metal plate to the one surface of the first collector 151 using an adhesive material.

The first signal line 154 may transmit the signal generated by the first signal pad 153 to the circuit. The first signal line 154 may be formed of a conductive material such as metal.

The second sensor 160 may include a second collector 161, a second insulating structure 162, a second signal pad 163, and a second signal line 164. The second sensor 160 may have a similar structure to the first sensor 150, except for the second insulating structure 162. For example, the second collector 161 may have a size and a shape, identical or similar to a size and a shape of the first collector 151, and an upper surface of the second collector 161 may be parallel or substantially coplanar with the upper surface of the upper plate 110.

In a different manner in which the step difference between the upper surface of the first insulating structure 152 and the upper surface of the first collector 151 is ‘0,’ a step difference between an upper surface of the second insulating structure 162 and the upper surface of the second collector 161 may be greater than ‘0.’ Due to a difference between the step difference of the first insulating structure 152 and the step difference of the second insulating structure 162, a direction range in which positive ions are incident on the first collector 151 and the second collector 161 may be changed. The plasma parameter in a lateral direction may be measured, based on the differential signal between the first signal generated from the first sensor 150 and the second signal generated from the second sensor 160.

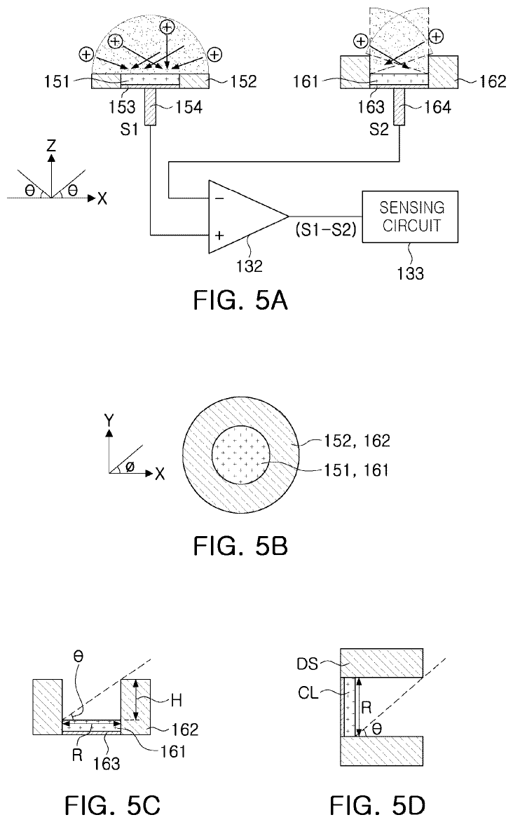

A method for measuring a plasma parameter using a sensor pair including the first sensor 150 and the second sensor 160, and various implementations of the sensor pair will be described later with reference to FIGS. 5A to 8.

The third sensor 170 may include a third collector 171, a third insulating structure 172, a third signal pad 173, a third signal line 174, an actuator 175, and a control signal line 176. The third collector 171, the third insulating structure 172, and the third signal pad 173 of the third sensor 170 may have a similar structure to the second collector 161, the second insulating structure 162, and the second signal pad 163 of the second sensor 160. For example, like the second insulating structure 162, an upper surface of the third insulating structure 172 and an upper surface of the third collector 171 may have a step difference greater than ‘0’.

The actuator 175 may move a structure including the third collector 171, the third insulating structure 172, and the third signal pad 173, based on a control signal from the circuit, and may control a direction in which a surface of the third collector 171 faces. The control signal line 176 may transmit the control signal generated from the circuit to the actuator 175. The third signal line 174 may be implemented as a wire to provide flexible movement of the structure.

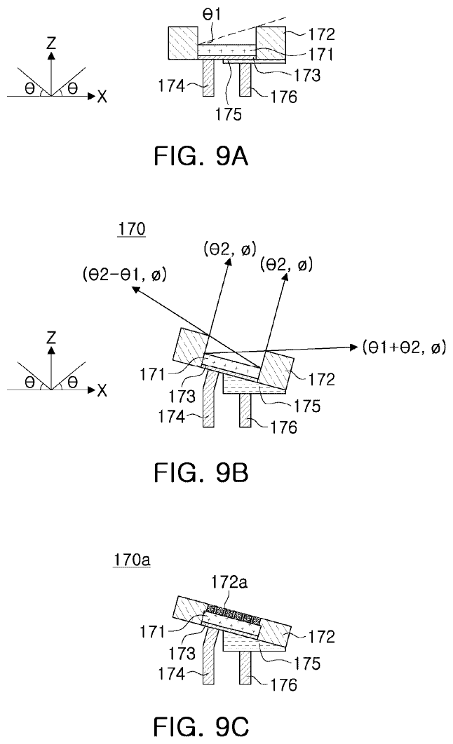

The third sensor 170 may measure the plasma parameter in a desired (and/or alternatively predetermined) direction range, based on the direction in which the surface of the third collector 171 faces. A method for measuring a plasma parameter using the third sensor 170, and various implementations of the third sensor 170 will be described later with reference to FIGS. 9A and 9B.

The fourth sensor 180 may include a fourth collector 181, a fourth insulating structure 182, a fourth signal pad 183, and a fourth signal line 184. The fourth sensor 180 may have a similar structure to the first sensor 150 or the second sensor 160. In a different manner in which the upper surface of the first collector 151 of the first sensor 150 and the second collector 161 of the second sensor 160 are parallel to the upper surface of the upper plate 110, the fourth sensor 180 may be disposed on a side surface of the plasma parameter measurement device 100, such that an upper surface of the fourth collector 181 may be perpendicular to the upper surface of the upper plate 110.

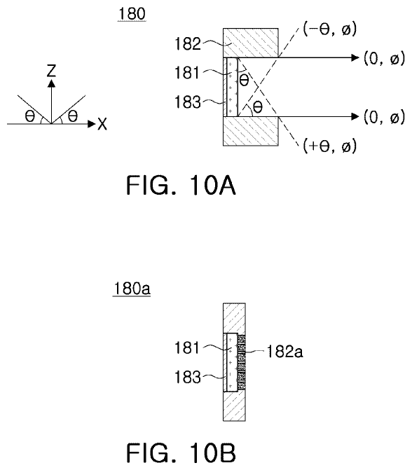

The fourth sensor 180 may measure the plasma parameter in a desired (and/or alternatively predetermined) direction range, based on a direction in which a surface of the fourth collector 181 faces. A method for measuring a plasma parameter using the fourth sensor 180, and various implementations of the fourth sensor 180 will be described later with reference to FIGS. 10A and 10B.

FIGS. 5A to 5D are views illustrating a sensor pair in detail, according to various example embodiments.

FIG. 5A illustrates a first sensor 150 and a second sensor 160, and a partial configuration of a circuit that may be formed on a circuit substrate 130, as described with reference to FIG. 4.

In FIG. 5A, cross-sections of the first sensor 150 and the second sensor 160 cut along an X-Z plane are illustrated. A direction in which ions are incident may be defined, based on an angle that the direction is disposed relative to a Z-axis. An angle parallel to the Z-axis, for example, an angle perpendicular to a first collector 151 and a second collector 161 may be defined as 90°, and as an angle with the Z-axis increases, the angle may be defined as a lower angle. And, an angle parallel to an X-axis, for example, an angle parallel to the first collector 151 and the second collector 161, may be defined as 0°.

As described with reference to FIG. 4, a step difference between an upper surface of a first insulating structure 152 and an upper surface of the first collector 151 may be ‘0.’ The first collector 151 may collect positive ions incident from all directions on an upper surface of an upper plate 110, from positive ions (+) incident vertically to positive ions incident horizontally. A first signal pad 153 may convert amounts of collected positive ions into a first signal S1, and provide the first signal S1 to the circuit through a first signal line 154.

A step difference between an upper surface of a second insulating structure 162 and an upper surface of the second collector 161 may be greater than ‘0.’ The second collector 161 may collect amounts of positive ions incident in a limited direction range, which may be determined, based on a diameter of the upper surface of the first collector 161 and an aspect ratio determined by the step difference. For example, incident positive ions may be collected in a direction range from 90° perpendicular to the upper surface of the upper plate 110 to an angle θ determined based on the aspect ratio. A second signal pad 163 may convert amounts of collected positive ions into a second signal S2, and may provide the second signal S2 to the circuit through a second signal line 164.

The circuit may include a differential amplifier 132 and a sensing circuit 133. The differential amplifier 132 may output a differential signal between the first signal S1 and the second signal S2 to the sensing circuit 133. The sensing circuit 133 may measure a plasma parameter, for example, ion flux, using positive ions incident from a side surface, based on the differential signal. For example, the differential signal may correspond to a plasma parameter in a direction range from 0° parallel to the upper surface of the upper plate 110 to the angle 0.

FIG. 5B illustrates structures of the first sensor 150 and the second sensor 160 in the X-Y plane. Hereinafter, a direction based on the X-axis or Y-axis may be referred to as an orientation.

According to various example embodiments, the upper surfaces of the first collector 151 and the second collector 161 may have a circular shape. Since the upper surface of the second collector 161 has a circular shape, the second collector 161 may collect positive ions incident in the same direction range from all orientations. In this case, the orientation may be defined as an angle on the X-Y plane. Shapes of the first insulating structure 152 and the second insulating structure 162 are illustrated as being circular, but the shapes of the first insulating structure 152 and the second insulating structure 162 are not limited to being circular.

FIG. 5C illustrates an aspect ratio of the second sensor 160 and a direction range in which a plasma parameter may be detected according to the aspect ratio. The aspect ratio of the second sensor 160 may be defined as a ratio, i.e., (H/R) of a step difference H between the upper surface of the second insulating structure 162 and the upper surface of the second collector 161 relative to a diameter R of the upper surface of the second collector 161.

The direction range of the plasma parameter that may be measured by a sensor pair including the first sensor 150 and the second sensor 160 may be determined based on the aspect ratio of the second sensor 160. Specifically, a differential signal (S1-S2) between the first signal S1 and the second signal S2 may correspond to a plasma parameter in a direction range corresponding to a difference between a direction range in which positive ions are incident on the first collector 151 and a direction range in which positive ions are incident on the second collector 161. Therefore, the direction range of the plasma parameter that may be measured by the sensor pair may include a range from 0° to θ. θ may be determined as an inverse tangent value of the aspect ratio (H/R).

According to various example embodiments, a plasma parameter in a lateral direction, including a direction, horizontal to the upper plate 110, may be measured using a sensor pair respectively having a collector having an upper surface, parallel to the upper plate 110.

According to various example embodiments, a thickness of a plasma parameter measurement device 100 may be reduced. The thickness of the plasma parameter measurement device 100 may be explained by comparing FIGS. 5C and 5D.

FIG. 5D illustrates a comparative example different from an inventive example. According to a comparative example, a sensor may be disposed on an upper plate such that a collector CL faces in a lateral direction to measure a plasma parameter in the lateral direction.

According to a comparative example, when forming a collector CL exposing the same area as a collector 161 of an inventive example, a sensor may, at least, protrude by a height corresponding to a sum of a diameter R of the collector CL and a thickness of an insulating structure DS from the upper plate. As a result, a maximum thickness of a plasma parameter measurement device may become thick, and it may be difficult to bring in the plasma parameter measurement device.

According to an inventive example, measurement of a plasma parameter in a lateral direction using a differential signal (S1-S2) between a first signal S1 and a second signal S2 may reduce a maximum thickness of a plasma parameter measurement device 100. For example, a height of a sensor capable of measuring the plasma parameter in a direction range from 0° to 45° or less in the Z-direction may be less than or equal to a diameter R of an upper surface of a collector. A protruding height of the sensor capable of measuring the plasma parameter in a direction range from 0° to 11.3° may be only ⅕ of the diameter R of the upper surface of the collector.

In addition, in a plasma parameter measurement device according to a comparative example, not only a direction but also an orientation in which plasma is incident are limited, depending on an orientation in which an exposed area of the collector CL faces. Therefore, it may be difficult for the plasma parameter measurement device to measure a plasma parameter in a desired (and/or alternatively predetermined) direction range in all orientations.

According to various example embodiments, a plasma parameter measurement device 100 may measure a plasma parameter in a lateral direction using a differential signal (S1-S2) between a first signal S1 and a second signal S2 in a desired (and/or alternatively predetermined) direction range in all orientations.

Referring to FIGS. 5A to 5D, embodiments of a sensor pair in which a step difference of a first sensor 150 is ‘0’ and a step difference of a second sensor 160 is greater than ‘0’ are illustrated. The present inventive concepts are not limited thereto. For example, a sensor pair may include a first sensor 150 and a second sensor 160, having a step difference greater than ‘0,’ to measure plasma parameters in various direction ranges.

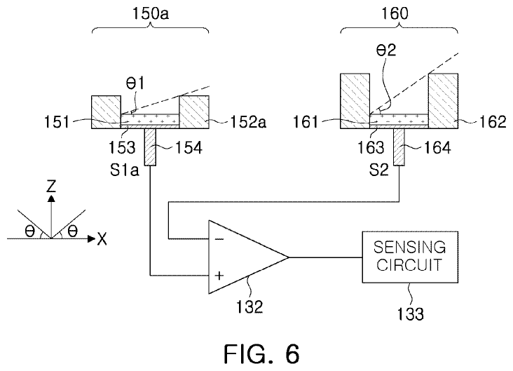

FIG. 6 is a view illustrating a sensor pair in detail, according to various example embodiments.

FIG. 6 illustrates a first sensor 150a, a second sensor 160, a differential amplifier 132, and a sensing circuit 133. A sensor pair in FIG. 6 may have the same structure as the sensor pair illustrated in FIG. 5A, except for a structure of the first sensor 150a. Hereinafter, differences between the sensor pair of FIG. 6 and the sensor pair of FIG. 5A will be described, focusing on the structure of the first sensor 150a.

According to various example embodiments, a first sensor 150a may include a first insulating structure 152a. A step difference between an upper surface of the first insulating structure 152a and an upper surface of a first collector 151 may be greater than ‘0.’ An aspect ratio of the first sensor 150a may be different from an aspect ratio of a second sensor 160.

According to various example embodiments, a plasma parameter may be measured in a direction range determined based on a differential signal between a first signal Sla output from the first sensor 150a and a second signal S2 output from the second sensor 160. A sensor pair including the first sensor 150a and the second sensor 160 may measure a plasma parameter in a direction range between a first angle θ1 defined by the aspect ratio of the first sensor 150a and a second angle θ2 defined by the aspect ratio of the second sensor 160.

A collector of each sensor included in a sensor pair, as described with reference to FIGS. 5A to 6, may have a single exposed surface, but the present inventive concepts are not limited thereto. For example, an insulating structure may further include a capillary structure covering an upper surface of the collector, and the collector may have a plurality of exposed surfaces passing through the capillary structure.

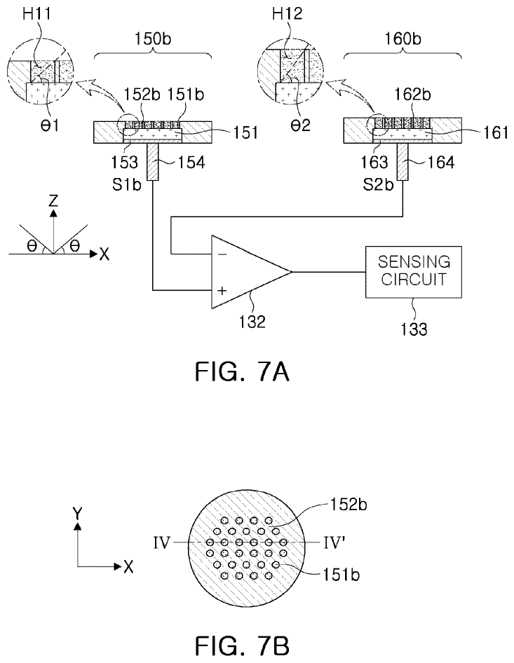

FIGS. 7A and 7B are views illustrating a sensor pair in detail, according to various example embodiments.

FIG. 7A illustrates a first sensor 150b, a second sensor 160b, a differential amplifier 132, and a sensing circuit 133. A differential amplifier 132 and a sensing circuit 133 of FIG. 7A may be the same as the differential amplifier 132 and the sensing circuit 133 described with reference to FIG. 5A. And, FIG. 7B illustrates a structure of a first sensor 150b in an X-Y plane.

A first sensor 150b and a second sensor 160b of FIG. 7A may be the same as the first sensor 150a and the second sensor 160 of FIG. 6, except for structures of a first insulating structure 152b and a second insulating structure 162b.

Referring to FIGS. 7A and 7B, a first insulating structure 152b may include a plurality of capillaries. The first insulating structure 152b may be formed to cover an upper surface of a first collector 151, and a portion of the upper surface of the first collector 151 may be exposed by the capillaries included in the first insulating structure 152b. FIG. 7A illustrates a cross-section taken along line IV-IV′ of FIG. 7B in a first sensor 150b. FIGS. 7A and 7B illustrate one exposed surface 151b among a plurality of exposed surfaces of the first collector 151.

Like the first insulating structure 152b, a second insulating structure 162b may include a plurality of capillaries, and may be formed to cover an upper surface of a second collector 161. A portion of the upper surface of the second collector 161 may be exposed by the capillaries included in the second insulating structure 162b.

In various example embodiments, the first insulating structure 152b and the second insulating structure 162b may be manufactured by attaching a ready-made capillary plate to the upper surface of the first collector 151 and the upper surface of the second collector 161, respectively. The present inventive concepts are not limited thereto.

According to various example embodiments, a first aspect ratio determined as a ratio of a length relative to a diameter of a capillary of the first insulating structure 152b may be different from a second aspect ratio determined as a ratio of a length relative to a diameter of a capillary of the second insulating structure 162b.

A first sensor 150b may output a first signal S1b based on amounts of positive ions incident on a first capillary hole H11 in a direction range determined based on the first aspect ratio, and a second sensor 160b may output a second signal S2b based on amounts of positive ions incident on a second capillary hole H12 in a direction range determined based on the second aspect ratio. A differential amplifier 132 may determine a differential signal between the first signal S1b and the second signal S2b, and a sensing circuit 133 may measure a plasma parameter in a desired (and/or alternatively predetermined) direction range based on the differential signal.

Comparing the sensor pair in FIG. 6 with the sensor pair in FIG. 7A, diameters of exposed surfaces of the collectors 151 and 161 in FIG. 7AB may be smaller than diameters of exposed surface of the collectors 151 and 161 in FIG. 6, respectively. Therefore, a step difference between an upper surface of a collector and an upper surface of an insulating structure for implementing the same aspect ratio may be reduced. As a result, in the Z-direction, a thickness of a plasma parameter measurement device including the sensor pair of FIG. 7A may be smaller than a thickness of a plasma parameter measurement device including the sensor pair of FIG. 6.

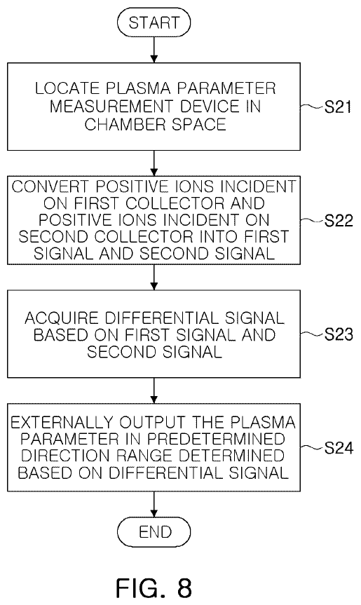

FIG. 8 is a flowchart illustrating a method for measuring a plasma parameter according to various example embodiments.

In S21, a plasma parameter measurement device may be located in a chamber space. The plasma parameter measurement device may have a sensor pair including a first sensor and a second sensor, as described with reference to FIGS. 5A to 7B. As previously described, the plasma parameter measurement device may be introduced into the chamber space in the same manner as a semiconductor substrate, and may be loaded on an electrostatic chuck in the chamber space. When the plasma parameter measurement device is located in the chamber space, a plasma process may be performed.

In S22, the plasma parameter measurement device may convert amounts of positive ions incident on a first collector of the first sensor into a first signal, and may convert amounts of positive ions incident on a second collector of the second sensor into a second signal.

As described with reference to FIGS. 5A to 7B, an aspect ratio of the first sensor may be different from an aspect ratio of the second sensor. In the embodiment of FIG. 5A, the aspect ratio of the first sensor may be ‘0,’ and the aspect ratio of the second sensor may be greater than ‘0.’ Depending on the aspect ratio of the first sensor and the aspect ratio of the second sensor, a range of direction which the positive ions incident on the first sensor and a range of direction which the positive ions incident on the second sensor may be changed.

In S23, the plasma parameter measurement device may acquire a differential signal based on the first signal and the second signal. The differential signal may represent a plasma parameter in a direction range corresponding to a difference between the direction range of the positive ions incident on the first sensor and the direction range of the positive ions incident on the second sensor.

In S24, the plasma parameter measurement device may externally output a value of the plasma parameter, for example, ion flux, in a desired (and/or alternatively predetermined) direction range determined based on the differential signal. For example, a circuit of the plasma parameter measurement device may include a wireless communication unit for outputting the plasma parameter externally. In addition, the plasma parameter may be received in real time externally, and the plasma parameter may be monitored over time during a plasma process.

FIGS. 9A to 9C are views illustrating a sensor in detail, according to various example embodiments.

FIGS. 9A and 9B illustrate structures of a third sensor 170, as described with reference to FIG. 4. FIG. 9A illustrates a structure of a third sensor 170 when an actuator 175 is in a first state, and FIG. 9B illustrates a structure of a third sensor 170 when an actuator 175 is in a second state. In various example embodiments, an actuator 175 may be implemented as a piezo actuator that expands or contracts, depending on a voltage to be applied.

Referring to FIG. 9A, when an actuator 175 is in a first state, an upper surface of a third collector 171 may be parallel to an upper surface of an upper plate 110, as described with reference to FIG. 4, The third sensor 170 may be accommodated in a third hole H3, as illustrated in FIG. 4.

Referring to FIG. 9B, when an actuator 175 is in a second state, an upper surface of a third collector 171 may be tilted to have a desired (and/or alternatively predetermined) direction and a desired (and/or alternatively predetermined) orientation according to deformation of the actuator 175. A degree to which the upper surface of the third collector 171 is tilted may be changed, depending on a voltage to be applied to the actuator 175.

According to various example embodiments, a third sensor 170 may measure a plasma parameter in a desired (and/or alternatively predetermined) direction range according to an aspect ratio of the third sensor 170 based on a diameter of an upper surface of a third collector 171, and a step difference between an upper surface of the third insulating structure 172 and the upper surface of the third collector 171, based on a direction and an orientation in which the upper surface of the third collector 171 faces.

The third collector 171 may collect positive ions incident in the desired (and/or alternatively predetermined) direction range, and a third signal pad 173 may convert amounts of the collected positive ions into a signal, and the converted signal may be output to a circuit through a third signal line 174. A sensing device of the circuit may measure a plasma parameter in the desired (and/or alternatively predetermined) direction range, based on the converted signal.

According to various example embodiments, a third sensor 170 may be accommodated in the third hole H3 when the plasma parameter measurement device 100 is introduced into or out of a chamber space, and may be tilted to have a desired (and/or alternatively predetermined) direction and a desired (and/or alternatively predetermined) orientation when a plasma parameter is measured. Therefore, when being introduced in or out, a thickness of the plasma parameter measurement device 100 may be reduced, and when a plasma parameter is measured, the plasma parameter in a lateral direction may be effectively measured.

FIG. 9C illustrates a third sensor 170a. The third sensor 170a of FIG. 9C may be the same as the third sensors 170 described with reference to FIGS. 9A and 9B, except for a structure of a third insulating structure 172a.

Referring to FIG. 9C, the third insulating structure 172a may include a plurality of capillaries. A structure of the third insulating structure 172a may be similar to a structure of the first insulating structure 152b and a structure of the second insulating structure 162b, described with reference to FIGS. 7A and 7B.

According to various example embodiments, the third sensor 170a may measure a plasma parameter in a desired (and/or alternatively predetermined) direction range according to an aspect ratio of the third sensor 170a determined as a ratio of a length relative to a diameter of a capillary of the third insulating structure 172a, based on a direction and an orientation in which the upper surface of the third collector 171 faces.

FIGS. 10A and 10B are views illustrating a sensor in detail, according to various example embodiments.

FIG. 10A illustrates a structure of a fourth sensor 180, as described with reference to FIG. 4. The fourth sensor 180 may be disposed on a side surface of a plasma parameter measurement device 100, as described with reference to FIG. 4. A fourth collector 181 of the fourth sensor 180 may have an outer side surface exposed to plasma. The outer side surface of the fourth collector 181 may be disposed to face a desired (and/or alternatively predetermined) orientation q in a direction, parallel to an upper surface of an upper plate 110.

According to various example embodiments, the fourth sensor 180 may measure a plasma parameter in a desired (and/or alternatively predetermined) direction range according to an aspect ratio of the fourth sensor 180 based on a diameter of an outer side surface of the fourth collector 181, and a step difference between an outer side surface of a fourth insulating structure 182 and the outer side surface of the fourth collector 181, based on a direction and an orientation in which the outer side surface of the fourth collector 181 faces.

FIG. 10A illustrates a case in which the step difference between the outer side surface of the fourth insulating structure 182 and the outer side surface of the fourth collector 181 is greater than ‘0,’ but the present inventive concepts are not limited thereto. The step difference between the outer side surface of the fourth insulating structure 182 and the outer side surface of the fourth collector 181 may be ‘0.’

The fourth collector 181 may collect positive ions incident in the desired (and/or alternatively predetermined) direction range. A fourth signal pad 183 formed on an inner side surface of the fourth collector 181 facing an inner side of the plasma parameter measurement device 100 may convert amounts of the collected positive ions into a signal, and the converted signal may be output to a circuit through a fourth signal line 184. A sensing device of the circuit may measure a plasma parameter in the desired (and/or alternatively predetermined) direction range based on the converted signal.

FIG. 10B illustrates a fourth sensor 180a. The fourth sensor 180a of FIG. 10B may have the same structure as the fourth sensor 180 described with reference to FIG. 10A, except for a structure of a fourth insulating structure 182a.

Referring to FIG. 10B, the fourth insulating structure 182a may include a plurality of capillaries. A structure of the fourth insulating structure 182a may be similar to a structure of the first insulating structure 152b and a structure of the second insulating structure 162b, described with reference to FIGS. 7A and 7B.

According to various example embodiments, the fourth sensor 180a may measure a plasma parameter in a desired (and/or alternatively predetermined) direction range according to an aspect ratio of the fourth sensor 180a determined as a ratio of a length relative to a diameter of a capillary of the fourth insulating structure 182a, based on a direction and an orientation in which an upper surface of a fourth collector 181 faces.

A plasma parameter measurement device 100, as described with reference to FIGS. 4 to 10B, may be disposed such that upper surfaces of collectors that collect incident positive ions are parallel to a surface of the plasma parameter measurement device 100 on which the collectors are arranged, and may measure a plasma parameter in a lateral direction based on positive ions collected by the collectors. A structure in which the collectors are arranged to be parallel to a surface to which a sensor is attached may reduce a maximum thickness of the plasma parameter measurement device 100. Therefore, a plasma parameter measurement device 100 according to various example embodiments may be introduced into a chamber space, and may measure the plasma parameters in the lateral direction in situ in a plasma process.

Even though in FIGS. 4 to 10B, cases in which the plurality of sensors 150 to 180 generates a current signal according to amounts of positive ions incident on the upper surfaces of the collectors are illustrated, the present inventive concepts are not limited thereto. For example, a plurality of sensors in a plasma parameter measurement device according to various example embodiments may measure a plasma parameter by converting positive ions incident on upper surfaces of collectors into an electrical signal or an optical signal.

A plasma parameter that may be measured by the plurality of sensors 150 to 180 is not limited to ion flux. For example, the plasma parameter may further include a parameter that may be determined by ions having directivity and be incident, such as an electron temperature, a plasma density, ion energy distribution, or the like.

A plasma parameter measurement device may include at least one sensor of a sensor pair, a third sensor, or a fourth sensor, as described with reference to FIGS. 4 to 10B, in plural. A plurality of sensors may be disposed at a plurality of positions of the plasma parameter measurement device, and the plasma parameter measurement device may measure distribution of a plasma parameter according to a region of the plasma parameter measurement device, based on signals acquired from the plurality of sensors.

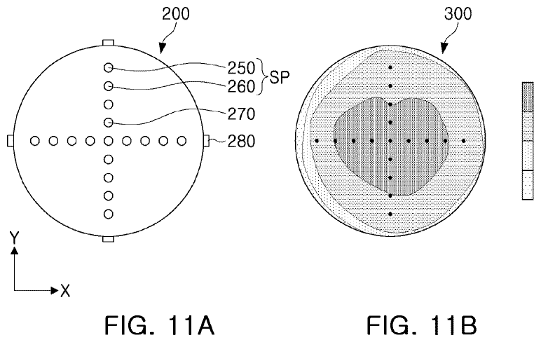

FIGS. 11A and 11B are views illustrating a plasma parameter measurement device and distribution of a plasma parameter according to various example embodiments.

FIG. 11A is a view illustrating a plasma parameter measurement device 200 according to various example embodiments in an X-Y plane. FIG. 11B illustrates plasma parameter distribution 300 of the plasma parameter measurement device 200.

In various example embodiments, a plasma parameter measurement device 200 may include a sensor pair SP including a first sensor 250 and a second sensor 260, a third sensor 270, and a fourth sensor 280. The sensor pair SP may correspond to those described with reference to FIGS. 5A to 7B, the third sensor 270 may correspond to those described with reference to FIGS. 9A to 9C, and the fourth sensor 280 may correspond to those described with reference to FIGS. 10A and 10B.

According to various example embodiments, a plurality of sensors may be arranged in a desired (and/or alternatively predetermined) pattern at a plurality of positions on upper and side surfaces of the plasma parameter measurement device 200. According to various example embodiments, a plurality of sensors may measure a plasma parameter at a plurality of positions in a plasma process environment, and may measure plasma parameter distribution based on the plasma parameter measured at the plurality of positions.

The plasma parameter measurement device 200 may include a plurality of sensor circuits and a central controller in a circuit therein. The plurality of sensor circuits measure a plasma parameter, based on a signal acquired from the plurality of sensors, and the central controller may collect a measurement value of the plasma parameter generated from the plurality of sensor circuits, to determine plasma parameter distribution.

A distribution diagram 300 illustrated in FIG. 11B may represent distribution of a plasma parameter, for example, ion flux. In the distribution diagram 300, a region illustrated with a darker pattern may indicate a region having a higher ion flux. In various example embodiments, the plasma parameter measurement device 200 may measure ion flux in the same direction range for each position using the same type of sensors. In addition, the distribution diagram 300 illustrating a magnitude of the ion flux for each position in the direction range may be generated based on the ion flux for each position in the central controller or externally.

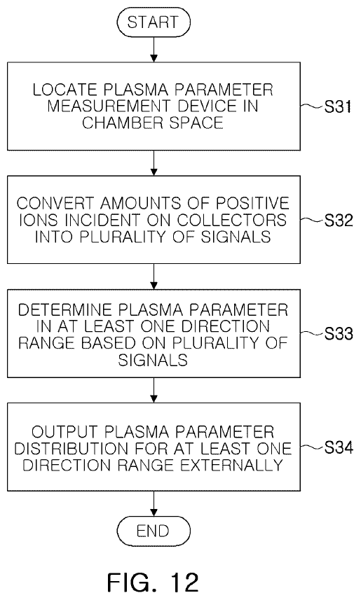

FIG. 12 is a flowchart illustrating a method for measuring distribution of a plasma parameter according to various example embodiments.

In S31, a plasma parameter measurement device may be located in a chamber space. As described with reference to FIG. 11, the plasma parameter measurement device may have a plurality of sensors arranged in a desired (and/or alternatively predetermined) pattern at a plurality of positions on upper and side surfaces. As previously described, the plasma parameter measurement device may be introduced into the chamber space in the same manner as a semiconductor substrate, and may be loaded on an electrostatic chuck in the chamber space. When the plasma parameter measurement device is located in the chamber space, a plasma process may be performed.

In S32, the plurality of sensors of the plasma parameter sensing device may convert amounts of positive ions incident on collectors into a plurality of signals.

In S33, the plasma parameter measurement device may determine a plasma parameter in at least one direction range, based on the plurality of signals. For example, based on the plurality of signals converted from the plurality of sensors, sensing circuits connected to the plurality of sensors may determine the plasma parameter in a desired (and/or alternatively predetermined) direction range at each of the plurality of positions of the plasma parameter measurement device.

In S34, the plasma parameter measurement device may output plasma parameter distribution for the at least one direction range externally. For example, the central controller of the plasma parameter measurement device may collect the plasma parameter determined at a plurality of positions, and may measure plasma parameter distribution for the at least one direction range. Additionally, the plasma parameter measurement device may output the plasma parameter distribution externally, and the plasma parameter may be monitored over time during a plasma process.

According to various example embodiments, distribution of the plasma parameter in a desired (and/or alternatively predetermined) direction range, for example, in a lateral direction, may be monitored, and may be determined whether an etching operation or the like in the lateral direction in the chamber may be performed evenly for each region of a substrate. As a result, the plasma parameters of a semiconductor manufacturing process may be monitored and may have improved control, therefore the plasma process quality may be improved which may improve the quality of the manufactured semiconductor devices.

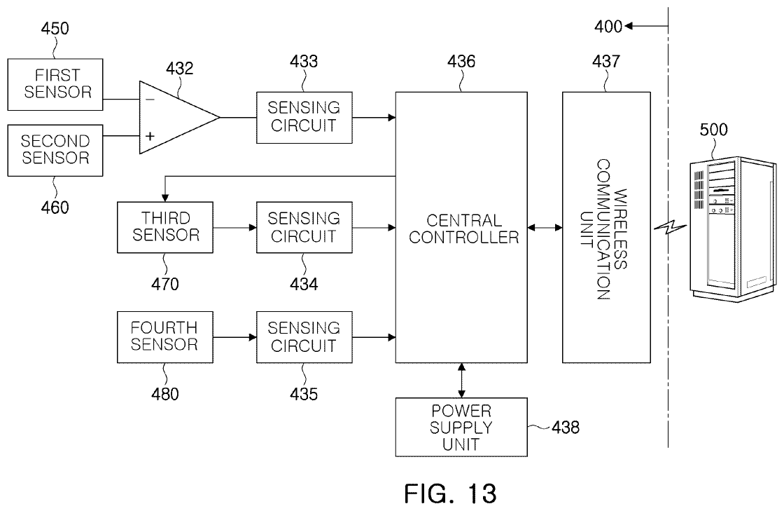

FIG. 13 is a view illustrating a plasma parameter measurement system according to various example embodiments.

A plasma parameter measurement system may include a plasma parameter measurement device 400 and an external server 500.

The plasma parameter measurement device 400 may include a circuit and a plurality of sensors 450, 460, 470, and 480. The circuit may include a differential amplifier 432, a plurality of sensing circuits 433, 434, and 435, a central controller 436, a wireless communication unit 437, and a power supply unit 438.

The differential amplifier 432 may output a differential signal between a first signal from a first sensor 450 and a second signal from a second sensor 460, to the sensing circuit 433. The first sensor 450 and the second sensor 460 may correspond to the first and second sensors, described with reference to FIGS. 5A to 7B, respectively.

For example, since the first sensor 450 and the second sensor 460 may have a collector, parallel to an upper surface of an upper plate, respectively, positive ions in a direction, perpendicular to the upper surface of the upper plate, will commonly be incident on the collector. Since an aspect ratio of the first sensor 450 is different from an aspect ratio of the second sensor 460, an incident direction range of the positive ions incident on the collector may be different. The sensing circuit 433 may use the differential signal to remove a vertical component, and may measure a plasma parameter in a lateral direction.

The sensing circuit 434 may measure a plasma parameter in a lateral direction using a signal from a third sensor 470. The third sensor 470 may correspond to the third sensor described with reference to FIGS. 9A to 9C. The third sensor 470 may be tilted by an actuator in a chamber space, and may thus measure a plasma parameter in a desired (and/or alternatively predetermined) direction range in a desired (and/or alternatively predetermined) orientation.

The sensing circuit 435 may measure a plasma parameter in a lateral direction using a signal from a fourth sensor 480. The fourth sensor 480 may correspond to the fourth sensor described with reference to FIGS. 10A and 10B. The fourth sensor 480 may be disposed on a side surface of the plasma parameter measurement device 400, and thus may thus measure a plasma parameter in a desired (and/or alternatively predetermined) direction range in a direction, parallel to the upper surface of the upper plate.

In various example embodiments, the plasma parameter measurement device 400 may include at least one sensor of a sensor pair including the first sensor 450 and the second sensor 460, the third sensor 470, or the fourth sensor 480. Also, a plurality of at least one type of sensor may be included.

The central controller 436 may generally control the plasma parameter measurement device 400. For example, values of the plasma parameters measured from the sensing circuits 433, 434, and 435 may be acquired, and plasma parameter distribution may be measured based on the values of the plasma parameters. In addition, the central controller 436 may control a measurement direction range of the third sensor 470 by controlling the actuator of the third sensor 470.

The wireless communication unit 437 may transmit the plasma parameter measurement values or the plasma parameter distribution to the external server 500.

The power supply unit 438 may supply power necessary for an operation of the plasma parameter measurement device 400. For example, the power supply unit 438 may include a battery for supplying the power to the plasma parameter measurement device 400 in a plasma process environment.

The external server 500 may receive plasma parameters or distribution of the plasma parameters, monitored from the plasma parameter measurement device 400, and may analyze a plasma process.

A plasma parameter measurement device according to various example embodiments may surround a collector in which positive ions are incident, with an insulating structure, to measure a plasma parameter having directivity in a desired (and/or alternatively predetermined) direction range.

In a plasma parameter measurement device according to various example embodiments, since an upper surface of a collector collecting positive ions is parallel to a surface on which collectors are arranged in the plasma parameter measurement device, a maximum thickness of the plasma parameter measurement device may decrease. As a result, the plasma parameter measurement device may be manufactured to have a size and a shape, similar to those of a substrate to be processed in the plasma processing device, and may measure the plasma parameter in a state loaded in a chamber space.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Problems to be solved by the present inventive concepts are not limited to the problems mentioned above, and other problems not mentioned will be clearly understood by those skilled in the art from the description below.

While various example embodiments have been illustrated and described above, it will be apparent to those skilled in the art that modifications and variations could be made without departing from the scope of the present inventive concepts as defined by the appended claims.

1. A plasma parameter measurement device comprising:
an upper plate and a lower plate comprising a first material, and the first material being included in a semiconductor substrate to be subjected to a plasma;
a first sensor including
a first collector comprising the first material, and
a first insulating structure surrounding a side surface of the first collector and exposing at least a portion of an upper surface of the first collector in a first hole in the upper plate, and
wherein a step difference between an upper surface of the first insulating structure and the upper surface of the first collector, relative to a diameter of an exposed surface of the first collector, has a first aspect ratio;
a second sensor including
a second collector comprising the first material, and
a second insulating structure surrounding a side surface of the second collector and exposing at least a portion of an upper surface of the second collector in a second hole in the upper plate, and
wherein a step difference between an upper surface of the second insulating structure and the upper surface of the second collector, relative to a diameter of an exposed surface of the second collector, has a second aspect ratio, the second aspect ratio being different from the first aspect ratio; and
a circuit substrate between the upper plate and the lower plate,
the circuit substrate including a circuit configured to measure a plasma parameter in a direction range, based on a differential signal between a first signal from the first sensor and a second signal from the second sensor.

2. The plasma parameter measurement device of claim 1, wherein the first aspect ratio is ‘0,’ and the second aspect ratio has a value greater than ‘0.’

3. The plasma parameter measurement device of claim 1, wherein the first aspect ratio and the second aspect ratio have a value greater than ‘0,’ respectively.

4. The plasma parameter measurement device of claim 1, wherein
the first insulating structure comprises
a first capillary plate on the upper surface of the first collector, and
a plurality of first capillaries exposing a portion of the upper surface, and the second insulating structure comprises
a second capillary plate on the upper surface of the second collector, and
a plurality of second capillaries exposing a portion of the upper surface, and
wherein the plurality of second capillaries have a different ratio of diameter and length from the plurality of first capillaries.

5. The plasma parameter measurement device of claim 1, wherein the first sensor further comprises
a first signal pad configured to generate a first signal according to an amount of positive ions incident on the upper surface of the first collector, and the second sensor further comprises
a second signal pad configured to generate a second signal according to an amount of positive ions incident on the upper surface of the second collector.

6. The plasma parameter measurement device of claim 5, wherein the first signal pad and the second signal pad comprise at least one of gold (Au) or tungsten (W).

7. The plasma parameter measurement device of claim 1, further comprising:
a filling material filling between the upper plate and the circuit substrate; and
the filling material filling between the lower plate and the circuit substrate.

8. The plasma parameter measurement device of claim 1, wherein the first insulating structure and the second insulating structure comprise at least one of quartz or glass.

9. The plasma parameter measurement device of claim 1, wherein the first material comprises silicon (Si).

10. The plasma parameter measurement device of claim 1, wherein the circuit comprises a wireless communication unit configured to transmit a measurement result of the plasma parameter externally.

11. The plasma parameter measurement device of claim 1, wherein the upper plate and the lower plate have a diameter of 100 mm to 500 mm, and
the plasma parameter measurement device has a thickness of 0.5 mm to 3 mm in a direction, perpendicular to an upper surface of the upper plate.

12. The plasma parameter measurement device of claim 1, further comprising:
a third sensor in a third hole in the upper plate;
the third sensor including
a third collector comprising the first material,
a third insulating structure surrounding a side surface of the third collector and exposing at least a portion of an upper surface of the third collector, and
the third insulating structure having a step difference between the upper surface of the third insulating structure and the upper surface of the third collector;
a third signal pad contacting a lower surface of the third collector; and
an actuator controlling an angle of the upper surface of the third collector.

13. The plasma parameter measurement device of claim 1, further comprising:
a fourth sensor on a side surface of the circuit substrate; and
the fourth sensor including
a fourth collector comprising the first material,
the fourth collector including
an inner side surface facing the circuit substrate,
an outer side surface opposite the inner side surface,
a fourth insulating structure surrounding the fourth collector and exposing at least a portion of the outer side surface of the fourth collector, and
the fourth insulating structure having a step difference between the outer side surface of the fourth insulating structure and a fourth signal pad contacting the inner side surface of the fourth collector.

14. A plasma parameter measurement device comprising:
an upper plate and a lower plate comprising a first material, and the first material being included in a semiconductor substrate to be subjected to a plasma;
a plurality of sensor pairs respectively including
a first sensor including
a first collector comprising the first material,
a first insulating structure surrounding a side surface of the first collector, and
the first insulating structure having an upper surface of the first insulating structure being coplanar with an upper surface of the first collector in a hole in the upper plate;
a second sensor including
a second collector comprising the first material, and
a second insulating structure surrounding a side surface of the second collector and having an upper surface protruding relative to an upper surface of the second collector in a hole in the upper plate; and
a circuit substrate between the upper plate and the lower plate including
a circuit configured to measure a distribution of a plasma parameter in a direction range on an upper surface of the upper plate,
wherein the measurement of the distribution of the plasma parameter is based on differential signals acquired by the first sensor and the second sensor in each of the plurality of sensor pairs.

15. The plasma parameter measurement device of claim 14, further comprising:
a plurality of third sensors respectively including
a third collector comprising the first material,
a third insulating structure surrounding the third collector, and
the third insulating structure having a step difference between an outer side surface of the third insulating structure and an outer side surface of the third collector; and
the plurality of third sensors on a side surface of the circuit substrate, and
wherein the circuit is further configured to measure a distribution of a plasma parameter in a direction range on a side surface of the plasma parameter measurement device, and
the measurement of the distribution of the plasma parameter is based on signals acquired by each of the plurality of third sensors.

16. The plasma parameter measurement device of claim 14, wherein the circuit comprises a wireless communication unit configured to transmit a measurement result of the distribution of the plasma parameter externally.

17. A plasma parameter measurement device comprising:
An upper plate and a lower plate comprising a first material, and the first material being included in a semiconductor substrate to be subjected to a plasma;
a circuit substrate between the upper plate and the lower plate and including a circuit; and
a sensor including
a collector comprising the first material, and
the collector including
an inner side surface facing the circuit substrate,
an outer side surface opposite the inner side surface,
an insulating structure surrounding the collector and exposing at least a portion of the outer side surface of the collector, and
a signal pad contacting the inner side surface of the collector on a side surface of the circuit substrate, and
wherein the circuit is configured to measure a plasma parameter in a direction range, based on a signal from the signal pad.

18. The plasma parameter measurement device of claim 17, wherein the insulating structure has a step difference from the outer side surface of the collector.

19. The plasma parameter measurement device of claim 17, wherein the direction range comprises a direction, parallel to the upper plate.

20. The plasma parameter measurement device of claim 17, wherein
the first material comprises silicon (Si), and
the insulating structure comprises at least one of quartz or glass.

21. (canceled)
